(19) United States
(12) Patent Application Publication
(10) Pub. No.: US 2010/0159400 A1
(43) Pub. Date: Jun. 24, 2010

(54) COMPOSITION FOR REMOVING A PHOTORESIST PATTERN AND METHOD OF FORMING A METAL PATTERN USING THE COMPOSITION

(75) Inventors: Sun-Young HONG, Yongin-si (KR); Nam-Seok SUH, Yongin-si (KR); Hong-Sik PARK, Suwon-si (KR); Sang-Dai LEE, Asan-si (KR); Young-Jin PARK, Asan-si (KR); Jong-Hyun CHOUNG, Hwaseong-si (KR); Bong-Kyun KIM, Incheon (KR); Byeong-Jin LEE, Seoul (KR)

Correspondence Address: H.C. PARK & ASSOCIATES, PLC, 8500 LEESBURG PIKE, SUITE 7500, VIENNA, VA, 22182, US

(73) Assignees: SAMSUNG ELECTRONICS CO., LTD., Suwon-si (KR); ENF TECHNOLOGY CO., LTD., Seoul (KR)

(21) Appl. No.: 12/629,597

(22) Filed: Dec. 2, 2009

(30) Foreign Application Priority Data
Dec. 24, 2008 (KR) 2008-133064

(51) Int. Cl. G03F 7/20; G03F 7/004

(52) U.S. Cl. 430/322; 430/331

(57) ABSTRACT

A composition for removing a photoresist pattern includes about 5 percent by weight to about 20 percent by weight of an aminoethoxy ethanol, about 2 percent by weight to about 10 percent by weight of a polyalkylene oxide, about 10 percent by weight to about 30 percent by weight of a glycol ether compound, and a remainder of an aprotic polar solvent including a nitrogen. Thus, the photoresist pattern can be easily removed from a substrate, thereby improving the removing ability of the composition. In addition, a residual amount of the photoresist pattern may be minimized, thereby improving the reliability of removing the photoresist pattern.

### CROSS REFERENCE TO RELATED APPLICATION

This application claims priority from and the benefit of Korean Patent Application No. 2008-133064, filed on Dec. 24, 2008, which is hereby incorporated by reference for all purposes as if fully set forth herein.

### BACKGROUND OF THE INVENTION

1. Field of the Invention

The present invention relates to a composition for removing a photoresist pattern and a method for forming a metal pattern using the composition. More particularly, embodiments of the present invention relate to a composition for removing a photoresist pattern for manufacturing a thin-film transistor (TFT) and a method of forming a metal pattern using the is composition.

2. Discussion of the Background

Generally, a photolithography process includes a photo process that transcribes a pattern formed in a mask to a substrate having a thin layer. The photolithography process may be used for manufacturing a semiconductor device, a display device such as a liquid crystal display (LCD) device, a flat panel display device, etc., which include an integrated circuit, a large-scale integrated circuit, etc.

The photolithography process includes a step of coating a photoresist including a photosensitive material on a base substrate, a step of disposing a mask on the base substrate having the photoresist, a step of exposing the substrate to light and a step of developing the photoresist to form a photoresist pattern. A thin layer formed on the base substrate is etched using the photoresist pattern as an etching mask to form a thin layer pattern. Thereafter, the photoresist pattern is removed from the base substrate by using a stripper.

The process of removing the photoresist pattern is generally performed at a relatively high temperature. For example, when the photoresist pattern is removed by the stripper at a high temperature, the stripper may react with a metal of a thin layer formed under the photoresist pattern thereby corroding the thin layer. In addition, when the photoresist pattern is removed through the stripper in a hydraulic cutting process, photoresist material removed from the substrate may be recombined with the substrate. The thin layer pattern may be damaged by the stripper remaining on the substrate and a cleaning solution used for washing the substrate.

In order to solve the above-mentioned problems, a corrosion inhibitor or a surfactant, etc., are added to a conventional stripper. However, when the stripper includes excessive additives such as the corrosion inhibitor and/or the surfactant, a removing ability of the composition may be reduced, and an improvement in efficiency of the stripper may be limited.

### SUMMARY OF THE INVENTION

Exemplary embodiments of the present invention provide a composition for removing a photoresist pattern. The composition minimizes damage of a lower thin layer pattern while having improved removing ability of the photoresist pattern. The composition also prevents a removed photoresist pattern from recombining with a substrate.

Exemplary embodiments of the present invention also provide a method for forming a metal pattern using the composition.

Additional features of the invention will be set forth in the description which follows, and in part will be apparent from the description, or may be learned by practice of the invention.

An exemplary embodiment of the present invention discloses a composition for removing a photoresist pattern comprising about 5 percent by weight to about 20 percent by weight of an aminoethoxy ethanol, about 2 percent by weight to about 10 percent by weight of a polyalkylene oxide compound, about 10 percent by weight to about 30 percent by weight of a glycol ether compound, and a remainder of an aprotic polar solvent including a nitrogen.

An exemplary embodiment of the present invention also discloses a method of forming a metal pattern. A photoresist pattern is formed on a metal layer that is formed on a substrate. The metal layer is patterned through the photoresist pattern and the photoresist pattern is removed from the substrate to form a metal pattern. In removing the photoresist pattern, the photoresist pattern is removed using a composition for removing a photoresist pattern, and the composition comprises about 5 percent by weight to about 20 percent by weight of an aminoethoxy ethanol, about 2 percent by weight to about 10 percent by weight of a polyalkylene oxide compound, about 10 percent by weight to about 30 percent by weight of a glycol ether compound, and an aprotic polar solvent including a nitrogen.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 and FIG. 2 are cross-sectional views illustrating a step of forming a gate pattern according to an example embodiment of the present invention.

FIG. 3 illustrates a photoresist removal apparatus used in a step of removing a photoresist pattern according to an exemplary embodiment of the present invention.

FIG. 4, FIG. 5, FIG. 6 and FIG. 7 are cross-sectional views illustrating a step of forming a source pattern according to an example embodiment of the present invention.

FIG. 8 is a cross-sectional view illustrating a step of forming a pixel electrode according to an example embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, a doped region illustrated as a rectangle may in fact have a rounded or curved boundary and further the dopant concentration may change gradually at the boundary rather than in an abrupt fashion. Likewise, in showing an implanted buried region, the drawings may omit a representation of a dopant implanted between the buried region and the surface through which the implantation takes place. Thus, the regions illustrated in the figures are schematic in nature and their shapes are not intended to illustrate the actual shape of a device and are not intended to limit the scope of the invention.

Hereinafter, the present invention will be described in detail with reference to the accompanying drawings.

Composition for Removing a Photoresist Pattern

According to an exemplary embodiment of the present invention, a composition for removing a photoresist pattern includes a) an aminoethoxy ethanol, b) a polyalkylene oxide compound, c) a glycol ether compound, and d) an aprotic polar solvent including nitrogen. The composition may further include e) a corrosion inhibitor. Hereinafter, components of the composition for removing a photoresist pattern according to an exemplary embodiment of the present invention will be more particularly described.

a) Aminoethoxy Ethanol

The aminoethoxy ethanol strongly penetrates into a polymer matrix of a photoresist pattern, which has a cross-linked structure, while an etching process or an ion implanting process, etc., is performed. Thus, the aminoethoxy ethanol may break an intermolecular attractive force or an intramolecular attractive force of the photoresist. Accordingly, an empty space is formed in a structurally weak area of a photoresist pattern remaining on a substrate, and the photoresist pattern is changed to have an amorphous gel state. Thus, the photoresist pattern may be separated from the substrate.

When a composition for removing a photoresist pattern includes a second amine and/or a third amine that are not aminoethoxy ethanol, a penetration rate of the composition for removing a photoresist pattern may be lower than that of the composition including aminoethoxy ethanol.

When a content of the aminoethoxy ethanol is less than about 5 percent by weight, the penetration rate is low so that the photoresist pattern is hardly removed. When a content of the aminoethoxy ethanol is more than about 20 percent by weight, a lower thin layer formed under the photoresist pattern is easily damaged. Thus, a content of the aminoethoxy ethanol is about 5 percent by weight to about 20 percent by weight.

b) Polyalkylene Oxide Compound

The polyalkylene oxide compound prevents the composition for removing a photoresist pattern from excessive evaporation in a hydraulic cutting process. Thus, the polyalkylene oxide compound prevents a photoresist material dissolved by the composition for removing a photoresist pattern from recombining with a substrate. The polyalkylene oxide compound has a very strong hydrophilicity so that the photoresist pattern is easily removed in a washing process using pure water.

The polyalkylene oxide compound may be represented by the following Chemical Formula 1.

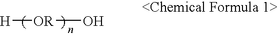

In Chemical Formula 1, “R” represents a hydrocarbon including carbon atoms of 1 to 4 and “n” represents an integer in a range of 1 to 50. For example, “R” may represent —(CH₂)—, —(CH₂)₂—, —(CH₂)₃—, or —(CH₂)₄—.

When “R” includes more than 5 carbon atoms, the polyalkylene oxide compound may not be dissolved in pure water in the washing process, which uses pure water, to remain on the substrate. Examples of the polyalkylene oxide compound may include polyethylene glycol, polypropylene glycol, etc.

When a content of the polyalkylene oxide compound is less than about 2 percent by weight, removing the photoresist pattern may be difficult because the residual amount of the polyalkylene oxide compound is excessively small after removing the photoresist pattern. When a content of the polyalkylene oxide compound is more than about 10 percent by weight, the removing ability of the composition may be reduced. Thus, a content of the polyalkylene oxide compound is about 2 percent by weight to about 10 percent by weight.

For example, the polyalkylene oxide compound may have a weight average molecular weight in a range of about 30 to about 600. When the weight average molecular weight is less than about 50, the photoresist pattern dissolved in the composition for removing a photoresist pattern may become solidified and recombine with the substrate because the residual amount of the polyalkylene oxide compound on the substrate is excessively small. When the weight average molecular weight is more than about 500, the viscosity of the composition for removing a photoresist pattern is high and reduces the removing ability of the composition. Thus, the polyalkylene oxide compound more preferably has a weight average molecular weight in a range of about 50 to about 500.

c) Glycol Ether Compound

The glycol ether compound is polar and protic. The photoresist pattern changed by the aminoethoxy ethanol to a gel state may be dissolved in the glycol ether compound. In addition, the glycol ether compound may prevent the composition for removing a photoresist pattern from being vaporized to maintain a ratio of components of the composition while a removing process is performed. Thus, an initial ratio of components of the composition for removing a photoresist pattern may be substantially the same as a ratio of components of the composition at the end of the removing process.

Examples of the glycol ether compound may include ethylene glycol methyl ether, ethylene glycol ethyl ether, ethylene glycol butyl ether, diethylene glycol methyl ether, diethylene glycol ethyl ether, diethylene glycol butyl ether, diethylene glycol propyl ether, triethylene glycol methyl ether, triethylene glycol ethyl ether, triethylene glycol butyl ether, etc.

When a content of the glycol ether compound is less than about 10 percent by weight, the composition for removing a photoresist pattern has a low wetting ability for the photoresist pattern. Thus, it may be difficult for the composition to have a uniform stripping characteristic. When a content of the glycol ether compound is more than about 30 percent by weight, a content of the polyalkylene oxide compound and/or a content of the aminoethoxy ethanol are relatively decreased, and thus the removing ability of the composition may be reduced. Thus, a content of the glycol ether compound is about 10 percent by weight to about 30 percent by weight.

d) Aprotic Polar Solvent including Nitrogen

The aprotic polar solvent including nitrogen may decompose the photoresist pattern detached from the substrate into unit-molecules. The unit-molecule may be dissolved in the composition for removing a photoresist pattern. In particular, a functional group of the aprotic polar solvent includes nitrogen to assist aminoethoxy ethanol in penetrating into the photoresist pattern to convert the photoresist pattern to a gel state for removal. In addition, the aprotic polar solvent including nitrogen has a chemical attraction to the aminoethoxy ethanol, thereby minimizing a component change due to vaporization of the composition for removing a photoresist pattern in the process of removing the photoresist pattern.

Examples of the aprotic polar solvent including nitrogen may include N-methyl-2-pyrrolidone, N-methyl acetamide, N,N′-dimethyl acetamide, acetamide, N′-ethyl acetamide, N,N′-diethyl acetamide, formamide, N-methyl formamide, N,N′-dimethyl formamide, N-ethyl formamide, N,N′-diethyl formamide, N,N′-dimethyl imidazole, N-aryl formamide, N-butyl formamide, N-propyl formamide, N-pentyl formamide, N-methylpyrrolidone, etc. When a viscosity of the aprotic polar solvent including nitrogen is low, a fluidity of the composition for removing a photoresist pattern is high to improve the removing ability of the composition. When a molecular weight of the aprotic polar solvent including nitrogen is small, a number of molecules per unit volume are large to increase a number of substrates capable of being treated by a predetermined quantity of the composition for removing a photoresist pattern. Thus, the viscosity of the aprotic polar solvent including nitrogen may be preferably about 0.01 centi Poise (cP) to 2 cP and the weight average molecular weight may be preferably about 50 to about 100. Examples of the aprotic polar solvent including nitrogen according to the above description may include N,N′-dimethyl acetamide, N-methyl formamide or N-methylpyrrolidone.

When a content of the aprotic polar solvent including nitrogen is more than about 80 percent by weight, a surface tension of the composition for removing a photoresist pattern is high so that the composition for removing a photoresist pattern has a low wetting ability for the photoresist pattern, thereby being difficult to have a uniform stripping characteristic. Thus, a content of the aprotic polar solvent including nitrogen is about 30 percent by weight to about 80 percent by weight.

e) Corrosion Inhibitor

The corrosion inhibitor may include a compound containing a nitrogen atom, a sulfur atom, an oxygen atom, etc., which have an unshared electron pair. Particularly, the compound may contain a hydroxyl group, a hydrogen sulfide group, etc. A reacting group of the corrosion inhibitor may physically and chemically adhere to a metal to prevent a corrosion of a metal thin layer including the metal.

The corrosion inhibitor includes a triazole compound. Examples of the triazole compound may include bezotriazole, tolyltrizole, etc.

When a content of the corrosion inhibitor is less than about 0.1 percent by weight, the metal thin layer may be corroded. When a content of the corrosion inhibitor is more than about 3 percent by weight, the corrosion inhibitor may be strongly adhered to the base substrate so that the corrosion inhibitor remains on the base substrate, or the remaining corrosion inhibitor may not be easily removed from the base substrate through a following cleaning process, thereby reducing the removability of the composition for removing a photoresist. Thus, a content of the corrosion inhibitor may be about 0.1 percent to about 3 percent by weight.

Hereinafter, a composition for removing a photoresist pattern according to an exemplary embodiment of the present invention will be described more fully with reference to examples and comparative examples. However, the present invention should not be construed as limited to the examples set forth herein.

### Examples 1 to 15

### Compositions for Removing a Photoresist Pattern

Compositions for removing a photoresist were prepared according to the following Table 1.

TABLE 1

| | | | | | | | | Polyalkylene | | | |
|---|---|---|---|---|---|---|---|---|---|---|---|
| | | Glycol ether | | Aprotic polar solvent | | | | oxide | | Corrosion | |
| | AEE | compound | | including nitrogen | | | | compound | | inhibitor | |
| Example | C | compound | C | compound | C | compound | C | compound | C | compound | C |
| 1 | 10 | MDG | 20 | NMF | 64.7 | — | — | PEG-200 | 5 | BT | 0.3 |
| 2 | 10 | EDG | 20 | NMF | 64.7 | — | — | PEG-200 | 5 | BT | 0.3 |
| 3 | 10 | BDG | 20 | NMF | 64.7 | — | — | PEG-200 | 5 | BT | 0.3 |
| 4 | 10 | DPGME | 20 | NMF | 64.7 | — | — | PEG-200 | 5 | BT | 0.3 |
| 5 | 10 | DPGME | 20 | DMAc | 64.7 | — | — | PEG-200 | 5 | BT | 0.3 |
| 6 | 10 | DPGME | 20 | NMP | 64.7 | — | — | PEG-200 | 5 | BT | 0.3 |
| 7 | 10 | DPGME | 15 | NMF | 54.7 | NMP | 15 | PEG-200 | 5 | BT | 0.3 |
| 8 | 10 | DPGME | 15 | DMAc | 54.7 | NMP | 15 | PEG-200 | 5 | BT | 0.3 |
| 9 | 10 | DPGME | 15 | NMP | 54.7 | NMF | 15 | PEG-200 | 5 | BT | 0.3 |
| 10 | 10 | DPGME | 15 | NMP | 54.7 | DMAc | 15 | PEG-200 | 5 | BT | 0.3 |
| 11 | 10 | DPGME | 15 | NMF | 56.7 | NMP | 15 | PEG-200 | 3 | BT | 0.3 |
| 12 | 10 | DPGME | 15 | NMF | 52.7 | NMP | 15 | PEG-200 | 7 | BT | 0.3 |
| 13 | 10 | DPGME | 15 | NMF | 54.7 | NMP | 15 | PEG-300 | 5 | BT | 0.3 |
| 14 | 10 | DPGME | 15 | NMF | 54.7 | NMP | 15 | PEG-500 | 5 | BT | 0.3 |
| 15 | | DPGME | 15 | NMF | 54.7 | NMP | 15 | PEG-700 | 5 | BT | 0.3 |

In Table 1, C represents a content of a component, of which a measurement unit is percent by weight. Furthermore, AEE represents 2-(2-aminoethoxy)ethanol, DMAc represents N,N′-dimethyl acetamide, NMF represents N-methyl formamide, NMP represents N-methyl-2-pyrrolidon, MDG represents diethylene glycol monomethyl ether, EDG represents diethylene glycol monoethyl ether, BDG represents diethylene glycol monobutyl ether, DPGME represents dipropylene glycol monomethyl ether, PEG-200 represents polyethylene oxide polymer having about 200 of a weight average molecular weight, PEG-300 represents polyethylene oxide polymer having about 300 of a weight average molecular weight, PEG-500 represents polyethylene oxide polymer having about 500 of a weight average molecular weight, PEG-700 represents polyethylene oxide polymer having about 700 of a weight average molecular weight, and BT represents benzotriazole.

### Comparative Examples 1 to 9

Comparative examples 1 to 9 were prepared according to the following Table 2.

TABLE 2

| | Alkanol | | | | Aprotic polar solvent | | | | Polyalkylene | | | |
|---|---|---|---|---|---|---|---|---|---|---|---|---|
| | amine | | Glycol ether | | including nitrogen | | | | oxide | | Corrosion | |
| | compound | | compound | | compound | | | | compound | | inhibitor | |
| CEx | cmpd | C | cmpd | C | compound | C | cmpd | C | cmpd | C | cmpd | C |
| 1 | AEE | 10 | DPGME | 15 | NMF | 59.7 | NMP | 15 | — | — | BT | 0.3 |
| 2 | AEE | 10 | DPGME | 15 | NMF | 59.7 | NMP | 15 | PEG-200 | 1 | BT | 0.3 |
| 3 | AEE | 10 | DPGME | 15 | NMF | 47.7 | NMP | 15 | PEG-200 | 12 | BT | 0.3 |
| 4 | AEE | 10 | DPGME | 15 | DMSO | 54.7 | NMP | 15 | PEG-200 | 5 | BT | 0.3 |
| 5 | AEE | 10 | DPGME | 15 | Sulfolane | 54.7 | NMP | 15 | PEG-200 | 5 | BT | 0.3 |
| 6 | MEA | 10 | DPGME | 15 | NMF | 54.7 | NMP | 15 | PEG-200 | 5 | BT | 0.3 |
| 7 | MIPA | 10 | DPGME | 15 | NMF | 54.7 | NMP | 15 | PEG-200 | 5 | BT | 0.3 |
| 8 | DEA | 10 | DPGME | 15 | NMF | 54.7 | NMP | 15 | PEG-200 | 5 | BT | 0.3 |
| 9 | TEA | 10 | DPGME | 15 | NMF | 54.7 | NMF | 15 | PEG-200 | 5 | BT | 0.3 |

In Table 2, CEx is an abbreviation for “Comparative example”, cmpd is an abbreviation for “compound”, C represents a content of a component, of which a measurement unit is percent by weight. Furthermore, AEE represents 2-(2-aminoethoxy)ethanol, MIPA represents monoisopropanol amine, DEA represents diethanol amine, TEA represents triethanol amine, NMF represents N-methyl formamide, NMP represents N-methyl-2-pyrrolidon, DPGME represents dipropylene glycol monomethyl ether, DMSO represents dimethyl sulfoxide, sulfolane represents 2,3,4,5-tetrahydrothiophene-1,1-dioxide, PEG-200 represents polyethylene oxide polymer having about 200 of a weight average molecular weight, and BT represents benzotriazole.

Manufacturing of Test Sample

A photoresist composition was coated on a substrate including a metal layer including an aluminum layer and a molybdenum layer, and exposure and developing processes were performed to form a photoresist pattern. The metal layer was etched through the photoresist pattern to form a metal pattern, thereby forming a test sample including the photoresist pattern and the metal pattern.

### Experiment 1

### Evaluation of a Removing Ability

Each test sample was dipped into each of the compositions according to Examples 1 to 15 and Comparative examples 1 to 9, which had a temperature of about 60° C., for about 1 minute. The test samples were then washed using pure water for about 30 seconds, and dried using nitrogen gas. Each of the dried test samples was observed to confirm if the photoresist pattern remained by using an optical microscope having a field-glass of about 200× magnification and a field emission scanning electron microscope (FE-SEM) having a magnification of about 2,000× to about 5,000×. The results thus obtained are illustrated in Table 3.

### Experiment 2

### Evaluation of a Treatment Capacity of a Composition

Each dried photo-pattern of about 0.5 percent based on a weight of a composition for removing a photoresist pattern was dissolved into each of the compositions according to Examples 1 to 15 and Comparative examples 1 to 9, which were maintained at a temperature of about 60° C. Each of the test samples was dissolved into each of the compositions according to Examples 1 to 15 and Comparative examples 1 to 9 for about 1 minute, and then washed using pure water for about 30 seconds, and dried using nitrogen gas. Each of the dried test samples was observed to confirm whether the photoresist pattern remained by using an optical microscope having a field-glass of about 200× magnification and an FE-SEM having a magnification of about 2,000× to about 5,000×. The results thus obtained are illustrated in Table 3.

In Experiment 2, a treatment capacity of the composition for removing a photoresist pattern can be evaluated through observing a removing rate, by which the photoresist pattern of the test sample was removed in the composition which already included the dried photo-pattern. It was defined that a treatment capacity was larger when the photoresist pattern did not remain than a treatment capacity when a portion of the photoresist pattern remained.

### Experiment 3

### Evaluation of a Recombining ability of a Photoresist Pattern

A dried photo-pattern of about 0.1 percent based on a weight of a composition for removing a photoresist pattern was dissolved into each of the compositions according to Examples 1 to 15 and Comparative examples 1 to 9, which were maintained at a temperature of about 60° C. Each of the test samples were dissolved into each of the compositions according to Examples 1 to 15 and Comparative examples 1 to 9 for about 2 minute, and then dried using nitrogen gas having a uniform pressure for about 10 seconds (a hydraulic cutting process), and then washed using pure water and dried using nitrogen gas. Each of the dried test samples was observed to confirm whether the photoresist pattern remained by using an optical microscope having a field-glass of about 200× magnification and an FE-SEM having a magnification of about 2,000× to about 5,000×. The results thus obtained are illustrated in Table 3.

In Experiment 3, the test sample was tested with the composition which already included the dried photo-pattern to evaluate a recombining rate of the photoresist pattern and the composition affected by the hydraulic cutting process using a high pressure. It was defined that the photoresist pattern was separated from the substrate by the composition including the photo-pattern, when the photoresist pattern did not remain. In addition, when the photoresist pattern did not remain, it was defined that the photoresist pattern and/or the photo-pattern was not recombined with the substrate in despite of performing the hydraulic cutting process. In addition, when a portion of the photoresist pattern remained, it was defined that a portion of the photoresist pattern and/or the photo-pattern remained with the substrate while performing the hydraulic cutting process.

In table 3, “CLEAN” represents that the photoresist pattern did not remain, “HR” represents that the photoresist pattern hardly remained, “Por” represents that a portion of the photoresist pattern remained, and “X” represents that a great portion of the photoresist pattern remained.

TABLE 3

| | | Treatment | Recombining |
|---|---|---|---|
| | Removing ability | capacity | ability |
| Example 1 | CLEAN | CLEAN | CLEAN |
| Example 2 | CLEAN | CLEAN | CLEAN |
| Example 3 | CLEAN | CLEAN | CLEAN |
| Example 4 | CLEAN | CLEAN | CLEAN |
| Example 5 | CLEAN | CLEAN | CLEAN |
| Example 6 | CLEAN | CLEAN | CLEAN |
| Example 7 | CLEAN | CLEAN | CLEAN |
| Example 8 | CLEAN | CLEAN | CLEAN |
| Example 9 | CLEAN | CLEAN | CLEAN |
| Example 10 | CLEAN | CLEAN | CLEAN |
| Example 11 | CLEAN | CLEAN | CLEAN |
| Example 12 | CLEAN | CLEAN | CLEAN |
| Example 13 | CLEAN | CLEAN | CLEAN |
| Example 14 | CLEAN | CLEAN | CLEAN |
| Example 15 | HR | HR | CLEAN |
| Comparative example 1 | CLEAN | CLEAN | X |
| Comparative example 2 | CLEAN | CLEAN | Por |
| Comparative example 3 | HR | HR | CLEAN |
| Comparative example 4 | CLEAN | Por | CLEAN |
| Comparative example 5 | CLEAN | Por | CLEAN |
| Comparative example 6 | CLEAN | CLEAN | CLEAN |
| Comparative example 7 | CLEAN | CLEAN | CLEAN |
| Comparative example 8 | HR | HR | CLEAN |
| Comparative example 9 | Por | Por | CLEAN |

### Experiment 4

### Evaluation of a Corrosion of a Lower Metal Layer

A first test sample including an aluminum thin layer, a second test sample including a molybdenum thin layer and a third test sample including a copper thin layer were dipped into each of compositions according to Examples 1 to 15 and Comparative examples 1 to 9, which had a temperature of about 60° C., for about 10 minutes. The test samples were then washed using pure water for about 30 seconds, and dried using nitrogen gas for about 10 seconds. Each of the dried test samples was observed to confirm if the photoresist pattern remained by using an optical microscope having a field-glass of about 200× magnifications and an FE-SEM having magnification of about 2,000× to about 5,000×. Results thus obtained are illustrated in Table 4.

In table 4, “PASS” represents that a surface of a metal thin layer pattern was not corroded, “SC” represents that a surface of a metal thin layer pattern was slightly corroded, “Par” represents that a surface of a metal thin layer pattern was partially corroded, and “Z” represents that a surface of a metal thin layer pattern was entirely corroded.

TABLE 4

| | Corrosion | | |
|---|---|---|---|
| | Copper | Aluminum | Molybdenum |
| | thin layer | thin layer | thin layer |
| | pattern | pattern | pattern |
| Example 1 | PASS | PASS | PASS |
| Example 2 | PASS | PASS | PASS |
| Example 3 | PASS | PASS | PASS |
| Example 4 | PASS | PASS | PASS |
| Example 5 | PASS | PASS | PASS |
| Example 6 | PASS | PASS | PASS |
| Example 7 | PASS | PASS | PASS |
| Example 8 | PASS | PASS | PASS |
| Example 9 | PASS | PASS | PASS |
| Example 10 | PASS | PASS | PASS |
| Example 11 | PASS | PASS | PASS |
| Example 12 | PASS | PASS | PASS |
| Example 13 | PASS | PASS | PASS |
| Example 14 | PASS | PASS | PASS |
| Example 15 | SC | PASS | PASS |
| Comparative example 1 | PASS | PASS | PASS |
| Comparative example 2 | PASS | PASS | PASS |
| Comparative example 3 | SC | PASS | PASS |
| Comparative example 4 | PASS | PASS | PASS |
| Comparative example 5 | PASS | PASS | PASS |
| Comparative example 6 | PASS | Z | Par |
| Comparative example 7 | PASS | Par | SC |
| Comparative example 8 | SC | PASS | PASS |
| Comparative example 9 | Par | PASS | PASS |

Referring to Table 3, it can be noted that the photoresist pattern is almost removed by the composition according to Examples 1 to 15, and that the treatment capacity is large. In addition, it can be noted that the photoresist pattern is barely recombined with the substrate although the hydraulic cutting process is performed when the photoresist pattern is removed using the composition according to Examples 1 to 15.

It can be noted that a portion of the photoresist pattern is recombined with the substrate to remain after completing a process for removing the photoresist pattern, when using the composition according to Example 15, although the removing ability and the treatment capacity are high. When the weight average molecular weight of the polyalkylene oxide compound is about 700, the photoresist pattern is easily recombined with the substrate compared to when the molecular weight thereof is about 200, about 300, and about 500. Thus, it can be noted that the weight average molecular weight of the polyalkylene oxide compound is preferably no more than about 500.

Referring to Table 4, it can be noted that the compositions according to Examples 1 to 15 form the copper thin layer pattern, the aluminum thin layer pattern and the molybdenum thin layer pattern without corrosion of the respective copper, aluminum and molybdenum.

It can be noted that the removing ability and the treatment capacity of the compositions according to Comparative examples 1 and 2 are high, and that the metal thin layer pattern is not corroded. However, it can also be noted that the compositions including less than about 1 percent by weight Polyalkylene oxide did not prevent recombining as well as that of the compositions according to Examples 1 to 15.

It can be noted that the recombining ability of the composition according to Comparative example 3 is low and that the metal thin layer pattern is not easily corroded, however, the removing ability and the treatment capacity are lower than those of the compositions according to Examples 1 to 15 because the composition according to Comparative example 3 includes the polyalkylene oxide compound of more than about 12 percent by weight.

It can be noted that the removing ability of the compositions according to Comparative examples 4 and 5 is high, the recombining ability is low, and the metal thin layer pattern is not easily corroded, however, the treatment capacity is lower than that of the compositions according to Examples 1 to 15, because each of the compositions according to Comparative examples 4 and 5 includes dimethyl sulfoxide and 2,3,4,5-tetrahydrothiophene-1,1-dioxide.

It can be noted that the removing ability and the treatment capacity of the compositions according to Comparative examples 6 and 7 are high and that the recombining ability is low, however the metal thin layer pattern is more easily corroded than that of the compositions according to Examples 1 to 15, because each of the compositions according to Comparative examples 6 and 7 includes monoethanol amine and monoisopropanol amine as the alkanol amine compound.

It can be noted that the recombining ability of the compositions according to Comparative examples 8 and 9 is low and that the metal thin layer pattern is not easily corroded, however, the removing ability and the treatment capacity are lower than those of the compositions according to Examples 1 to 15, because each of the compositions according to Comparative examples 8 and 9 includes diethanol amine and triethanol amine as the alkanol amine compound.

According to the above description, the damage of a lower thin layer pattern formed under a photoresist pattern may be minimized by using the composition for removing a photoresist pattern in removing the photoresist pattern. In addition, the composition for removing a photoresist pattern may prevent a photoresist material of the detached photoresist pattern from recombining with the substrate. Thus, the removing ability and the removing reliability may be improved.

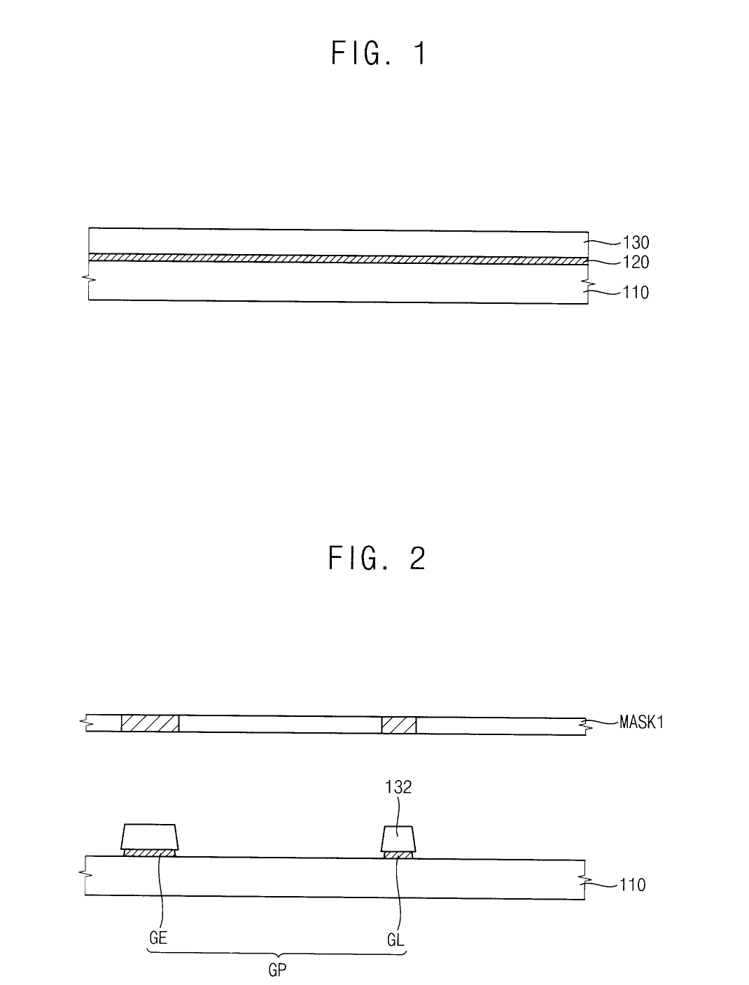

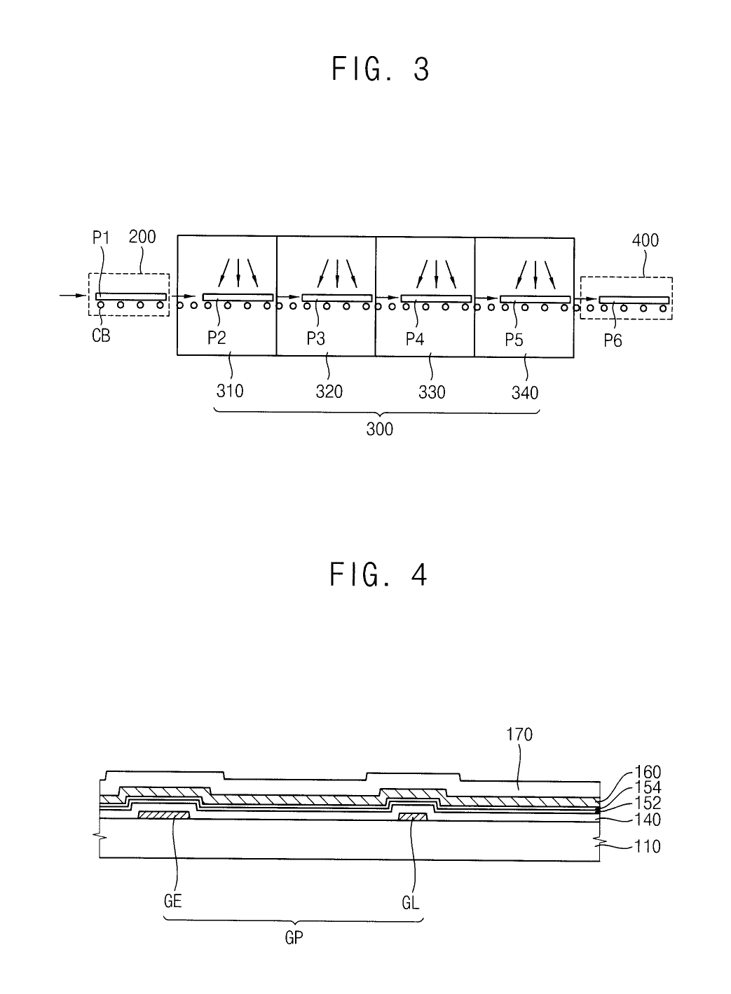

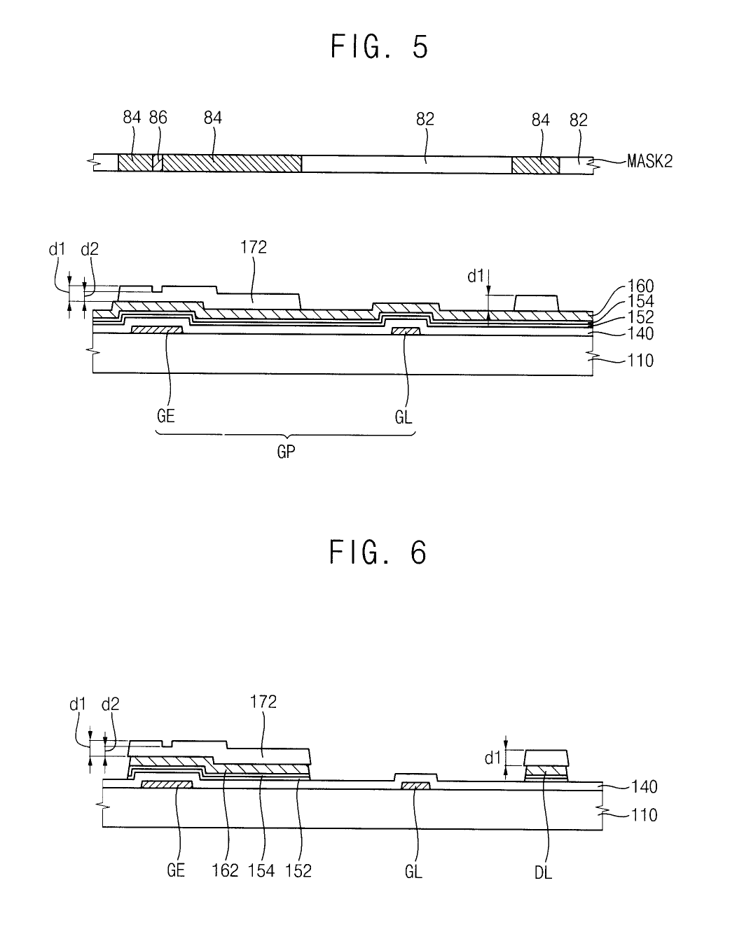

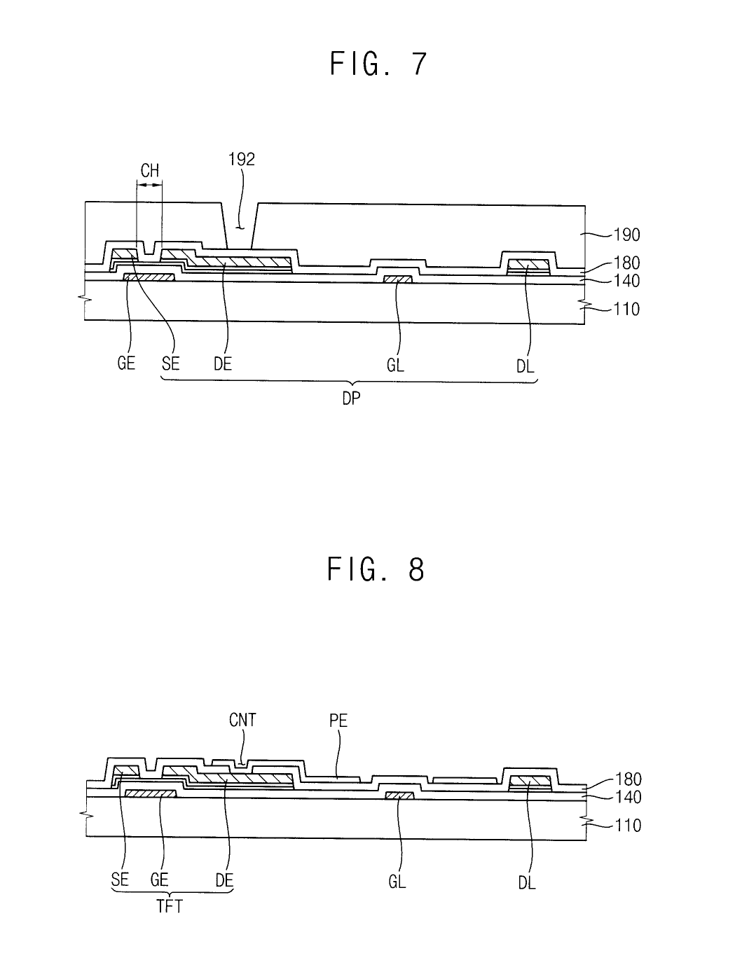

Hereinafter, a method of manufacturing a display substrate will be described referring to FIG. 1, FIG. 2, FIG. 3, FIG. 4, FIG. 5, FIG. 6, FIG. 7 and FIG. 8. The method includes a step of forming a metal pattern using the composition for removing a photoresist pattern. The metal pattern may be a gate pattern and/or a source pattern of the display substrate.

Method of Manufacturing a Display Substrate

FIG. 1 and FIG. 2 are cross-sectional views illustrating a step of forming a gate pattern according to an exemplary embodiment.

Referring to FIG. 1, a gate metal layer 120 is formed on a base substrate 110. Examples materials that may be used for the gate metal layer 120 include copper, molybdenum, aluminum, etc. These may be used alone or in combination thereof.

A first photoresist layer 130 is formed on the gate metal layer 120. A photoresist composition is dropped and coated on the base substrate 110 including the gate metal layer 120 to form the first photoresist layer 130. The photoresist composition may be coated on the base substrate 110 including the gate metal layer 120 by a slit coating process and/or a spin coating process. For example, the photoresist composition may be a positive type photoresist in which the photoresist composition is removed in an exposure region of the first photoresist layer 130 by an exposure solution.

Referring to FIG. 2, a first mask MASK1 is disposed over the base substrate 110 including the first photoresist layer 130. The light is irradiated to the first photoresist layer 130 over the first mask MASK1. The first photoresist layer 130 irradiated with the light is developed to form a first photoresist pattern 132.

The gate metal layer 120 is etched using the first photoresist pattern 132 as an etching mask to form a gate pattern GP. The gate pattern GP may include a gate line GL and a gate electrode GE. The gate line GL may extend in a direction of the base substrate 110. The gate electrode GE may be connected to the gate line GL.

The first photoresist pattern 132 formed on the gate pattern GP is removed using a composition for removing a photoresist pattern. The composition for removing a photoresist pattern includes about 5 percent by weight to about 20 percent by weight of an aminoethoxy ethanol, about 2 percent by weight to about 10 percent by weight of a polyalkylene oxide compound, about 10 percent by weight to about 30 percent by weight of a glycol ether compound, and a remainder of an aprotic polar solvent including a nitrogen. The composition for removing a photoresist pattern is substantially the same as the composition for removing a photoresist pattern as previously described. Thus, further repetitive detailed description will be omitted here. Hereinafter, a step of removing the first photoresist pattern 132 will be described with an apparatus for removing a photoresist pattern.

FIG. 3 illustrates a photoresist removal apparatus used in a step of removing a photoresist pattern according to an exemplary embodiment of the invention.

Referring to FIG. 3, the base substrate 110 is moved into an apparatus for removing a photoresist pattern in order to remove the first photoresist pattern 132 formed on the gate pattern GP. The apparatus for removing the photoresist pattern may include a chamber 300 and a moving device CB moving a substrate from a loading portion 200 to an unloading portion 400 through the chamber 300. The chamber 300 may be divided into a first bath 310, a second bath 320, a third bath 330 and a fourth bath 340. The substrate may be continuously moved by the moving device CB in the chamber 300. In another exemplary embodiment, the substrate may be moved into a next bath after staying in each bath for a time period.

A “first treating substrate” is defined to be a substrate initially disposed on the loading portion 200, and a reference mark for the first treating substrate in the drawings is “P1.” The first treating substrate P1 includes the gate pattern GP and the first photoresist pattern 132.

The first bath 310 may be a space spraying the composition for removing a photoresist pattern onto the first treating substrate P1 moved into the first bath 310. A “second treating substrate” is defined to be a substrate moved from the loading portion 200 to the first bath 310, and a reference mark for the second treating substrate in the drawings is “P2.” The composition for removing a photoresist pattern sprayed onto the second treating substrate P2 may drop toward a bottom of the first bath 310 by gravity and a portion of the composition for removing a photoresist pattern may remain on the second treating substrate P2. The composition for removing a photoresist pattern may dissolve the first photoresist pattern 132 of the second treating substrate P2. The composition for removing a photoresist pattern may only dissolve the first photoresist pattern 132 without damage of the gate pattern GP.

The second bath 320 is disposed between the first bath 310 and the third bath 330. The second bath 320 is connected to the first bath 310 and the third bath 330. A “third treating substrate” is defined to be a substrate moved from the first bath 310 to the second bath 320, and a reference mark for the third treating substrate in the drawings is “P3.” The second bath 320 may be a space spraying a high pressure gas onto the third treating substrate P3 in order to remove a portion of the composition for removing a photoresist pattern. The composition for removing a photoresist pattern prevents the first photoresist pattern 132 from recombining with the third treating substrate P3, because the composition for removing a photoresist pattern is not excessively dried by the high pressure gas. Thus, the first photoresist pattern 132 may be easily removed in the third bath 320 of a following process.

The third bath 330 is disposed between the second bath 320 and the fourth bath 340. The third bath 330 is connected to the second bath 320 and the fourth bath 340. A “fourth treating substrate” is defined to be a substrate moved from the second bath 320 to the third bath 330, and a reference mark for the fourth treating substrate in the drawings is “P4.” The third bath 330 may be a space removing the composition for removing a photoresist pattern and the dissolved first photoresist pattern 132, from the fourth treating substrate P4 using pure water, thereby washing the substrate. The composition for removing a photoresist pattern has a high chemical attraction to pure water so that the composition may be easily removed from the fourth treating substrate P4 in the third bath 330. By removing the composition for removing a photoresist pattern from the fourth treating substrate P4, the first photoresist pattern 132 may be simultaneously removed with the composition for removing a photoresist pattern. In addition, when pure water is provided to the fourth treating substrate P4, the composition for removing a photoresist pattern does not include a component reacting with the pure water so that generation of bubbles is prevented. Thus, bubbles causing contamination of a surface of the fourth treating substrate is essentially prevented.

The fourth bath 340 may be a space where a substrate is dried after washing through pure water. A “fifth treating substrate” is defined to be a substrate that is moved from the third bath 330 to the fourth bath 340, and a reference mark for the fifth treating substrate in the drawings is “P5.” In an exemplary embodiment, the fifth substrate P5 is dried using gas. Thus, the first photoresist pattern 132 is removed from the base substrate 110.

A “sixth treating substrate” is defined to be a substrate, from which the first photoresist pattern 132 is removed thereby only including gate pattern GP, and a reference mark for the sixth treating substrate in the drawings is “P6.” The sixth treating substrate P6 is moved from the fourth bath 340 to the unloading portion 400, thereby finishing a process for removing the first photoresist pattern 132.

FIG. 4, FIG. 5, FIG. 6 and FIG. 7 are cross-sectional views illustrating steps of forming a source pattern according to an exemplary embodiment of the invention.

Referring to FIG. 4, a gate insulation layer 140, a semiconductor layer 152 and a source metal layer 160 are formed on the base substrate 110 including the gate pattern GP. A second photoresist layer 170 is formed on the source metal layer 160. Examples of a material that may be used for the source metal layer 160 include copper, molybdenum, aluminum, etc. These may be used alone or in combination thereof. The second photoresist layer 170 may be a positive type photoresist.

Referring to FIG. 5, a second mask MASK2 is disposed over the base substrate 110 including the second photoresist layer 170. The light is irradiated to the second photoresist layer 170 through the second mask MASK2, thereby forming a second photoresist pattern 172. The second mask MASK2 includes a light-transmitting portion 82, a light-blocking portion 84 and a half light-transmitting portion 86.

The second photoresist layer 170 facing the light-transmitting portion 82 is removed using a developing solution. The second photoresist layer 170 facing the light-blocking portion 84 is developed to form a first thickness portion “d1” having substantially the same thickness as a thickness of the second photoresist layer 170 before being developed. The second photoresist layer 170 facing the half light-transmitting portion 86 is developed to form a second thickness portion “d2” thinner than the first thickness portion “d1.” Thus, the second photoresist pattern 172 including the first and second thickness portions “d1” and “d2” is formed on the source metal layer 160.

Referring to FIG. 6, the source metal layer 160 is etched using the second photoresist pattern 172 as an etching mask to form a first source pattern. The first source pattern includes a data line DL and a switching pattern 162 connected to the data line DL. The data line DL extends in a direction different from an extending direction of the gate line GL to cross the gate line GL.

The source metal layer 160 is patterned using an etching solution to form the first source pattern. An ohmic contact layer 154 and the semiconductor layer 152 are etched by using the second photoresist pattern 172 and the switching pattern 162 as etching masks. The second photoresist pattern 172 is ashed to remove the thickness portion “d2” and to form a residual photo pattern (not shown) thinner than the first thickness portion “d1.”

Referring to FIG. 7, the switching pattern 162 exposed through the residual photo pattern is removed by using the residual photo pattern as an etching mask. Thus, a source electrode SE connected to the data line DL and a drain electrode DE spaced apart from the source electrode SE are formed. A source pattern DP including the data line DL, the source electrode SE, and the drain electrode DE is formed on the base substrate 110 including the gate insulation layer 140.

The ohmic contact layer 154 exposed between the source electrode SE and the drain electrode DE is removed using the source pattern DP and the residual photo pattern as etching masks. Thus, a channel CH is formed.

The residual photo pattern on the base substrate 110 is removed by using the apparatus for removing a photoresist pattern shown in FIG. 3. The residual photo pattern is removed using a composition for removing a photoresist pattern substantially the same as the composition used in removing the first photoresist pattern. Removing the residual photo pattern is substantially the same as removing the first photoresist pattern. Thus, further repetitive detailed description will be omitted here.

The residual photo pattern is easily removed using the composition for removing a photoresist pattern. The composition for removing a photoresist pattern prevents the residual photo pattern from recombining with the base substrate. In addition, the damage of the source pattern DP is minimized by using the composition for removing a photoresist pattern.

A passivation layer 180 is formed on the base substrate 110 having the source pattern DP. A positive type photoresist composition is coated to form a third photoresist layer 190 having a hole 192. The passivation layer 180 formed on the drain electrode DE is exposed through the hole 192.

FIG. 8 is a cross-sectional view illustrating a step of forming a pixel electrode according to an exemplary embodiment.

Referring to FIG. 8, the passivation layer 180 is etched using the third photoresist pattern 190 as an etching mask to form a contact hole CNT. An edge portion of the drain electrode DE is exposed through the contact hole CNT. The third photoresist pattern 190 is removed by using the apparatus for removing a photoresist pattern shown in FIG. 3 and the composition for removing a photoresist pattern. Removing the third photoresist pattern is substantially the same as removing the first photoresist pattern. Thus, further repetitive detailed description will be omitted here.

A transparent electrode layer is formed on the passivation layer 180 including the contact hole CNT and a fourth photoresist layer (not shown) is formed on the transparent electrode layer. The fourth photoresist layer is patterned to form a fourth photoresist pattern (not shown). The transparent electrode layer is patterned using the fourth photoresist pattern as an etching mask to form a pixel electrode PE electrically connected to the drain electrode DE. The fourth photoresist pattern is removed by using the apparatus for removing a photoresist pattern shown in FIG. 3 and the composition for removing a photoresist pattern. Removing the fourth photoresist pattern is substantially the same as removing the first photoresist pattern. Thus, further repetitive detailed description will be omitted here.

According to an exemplary embodiment of the present invention, a composition for removing a photoresist pattern is used in a photolithography process in order to manufacture a display device such as a semiconductor device, a liquid crystal display device, a flat panel display device, etc. The corrosion of a metal layer including copper, molybdenum or aluminum may be prevented and/or reduced by using the composition for removing a photoresist pattern in the photolithography process.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A composition for removing a photoresist pattern, the composition comprising:
5 percent by weight to 20 percent by weight of an aminoethoxy ethanol;
2 percent by weight to 10 percent by weight of a polyalkylene oxide compound;
10 percent by weight to 30 percent by weight of a glycol ether compound; and
a remainder of an aprotic polar solvent including a nitrogen.

2. The composition of claim 1, wherein the polyalkylene oxide compound has a weight average molecular weight in a range from 50 to 500.

3. The composition of claim 1, wherein the polyalkylene oxide compound is represented by Chemical Formula 1, 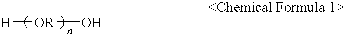
wherein “R” represents a hydrocarbon including 1 to 4 carbon atoms and “n” represents an integer in a range from 1 to 50.

4. The composition of claim 1, wherein the glycol ether compound comprises at least one selected from the group consisting of diethylene glycol monomethyl ether, diethylene glycol monoethyl ether, diethylene glycol monobutyl ether and dipropylene glycol monoethyl ether.

5. The composition of claim 1, wherein the aprotic polar solvent comprises at least one selected from the group consisting of N,N′-dimethylacetamide (DMAc), N-methylformamide (NMF) and N-methylpyrrolidone (NMP).

6. The composition of claim 1, further comprising a triazole compound as a corrosion inhibitor.

7. The composition of claim 6, wherein a content of the triazole compound is 0.1 percent by weight to 3 percent by weight.

8. A method of forming a metal pattern, the method comprising:
forming a photoresist pattern on a metal layer formed on a substrate;
patterning the metal layer using the photoresist pattern; and
removing the photoresist pattern using a composition for removing a photoresist pattern, the composition comprising 5 percent by weight to 20 percent by weight of an aminoethoxy ethanol, 2 percent by weight to 10 percent by weight of a polyalkylene oxide compound, 10 percent by weight to 30 percent by weight of a glycol ether compound, and a remainder of an aprotic polar solvent including a nitrogen.

9. The method of claim 8, wherein the photoresist pattern is removed by:
providing the substrate including the photoresist pattern with the composition for removing a photoresist pattern to dissolve the photoresist pattern; and
removing the photoresist pattern dissolved in the composition for removing a photoresist pattern to wash the substrate.

10. The method of claim 9, further comprising providing a high pressure gas to the substrate after providing the substrate with the composition for removing a photoresist pattern and before washing the substrate.

11. The method of claim 8, wherein the metal layer comprises at least one selected from the group of copper, aluminum and molybdenum.

12. The method of claim 8, wherein the polyalkylene oxide compound has a weight average molecular weight in a range from 50 to 500.

13. The method of claim 8, wherein the polyalkylene oxide compound is represented by Chemical Formula 1, 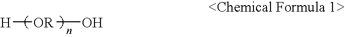
wherein “R” represents a hydrocarbon including 1 to 4 carbon atoms and “n” represents an integer in a range from 1 to 50.

14. The method of claim 8, wherein the glycol ether compound comprises:
at least one selected from the group consisting of diethylene glycol monomethyl ether, diethylene glycol monoethyl ether, diethylene glycol monobutyl ether and dipropylene glycol monoethyl ether.

15. The method of claim 8, wherein the aprotic polar solvent comprises:
at least one selected from the group consisting of N,N′-dimethylacetamide (DMAc), N-methylformamide (NMF) and N-methylpyrrolidone (NMP).

16. The method of claim 8, further comprising a triazole compound as a corrosion inhibitor.

17. The method of claim 16, wherein a content of the triazole compound is 0.1 percent by weight to 3 percent by weight.
